(19) United States
(12) Patent Application Publication
(10) Pub. No.: US 2009/0159324 A1
(43) Pub. Date: Jun. 25, 2009

(54) PRINTED CIRCUIT BOARD AND METHOD OF PRODUCING THE SAME

(75) Inventors: Akihiko Happoya, Tokyo (JP); Gen Fukaya, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/340,435

(22) Filed: Dec. 19, 2008

(30) Foreign Application Priority Data
Dec. 25, 2007 (JP) 2007-332932

(51) Int. Cl. H05K 1/02; H05K 3/02

(52) U.S. Cl. 174/261; 29/846

(57) ABSTRACT

According to one embodiment, a printed circuit board includes: a product portion having a given outer shape; and a cutout portion disposed in the given outer shape of the product portion, for being removed away in a later production step. The cutout portion comprises a test coupon including two signal terminals and two parallel wiring patterns meanderingly extended respectively from the two signal terminals.

### CROSS-REFERENCE TO RELATED APPLICATIONS

This application is based upon and claims the benefit of priority from Japanese Patent Application No. 2007-332932, filed Dec. 25, 2007, the entire contents of which are incorporated herein by reference.

### BACKGROUND

1. Field

One embodiment of the invention relates to a printed circuit board comprising a test coupon, and a method of producing the printed circuit board.

2. Description of the Related Art

A related art, for example, JP-A-2005-123228 discloses a printed circuit board in which printed coils are formed. In the related-art printed circuit board, in order to increase the production number of printed coils, test coupons for quality inspection are formed in core hole areas of the printed coils. Quality inspection of the printed coils is performed by using the test coupons formed in the core hole areas.

In order to form a wiring pattern of a test coupon in a printed circuit board, a large area may be required. For example, a test coupon for measuring a differential impedance in high-speed signal transmission has a wiring pattern in which two parallel wirings are linearly extended. Therefore, the test coupon requires an area corresponding to the extended length of the wiring pattern. The extended length of the wiring pattern is relatively large. Consequently, there is a limitation to form the wiring pattern in a cutout portion of a small area, such as the core hole area of the printed coil shown in the related-art.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view showing a printed circuit board of an embodiment before cutout.

FIG. 2 is a plan view showing an individual printed circuit board in the embodiment.

FIG. 3 is a view showing a test coupon formed in a cutout portion in the embodiment.

FIG. 4 is a view showing a printed circuit board other than the embodiment.

FIG. 5 is a flowchart showing production steps of the printed circuit board of the embodiment.

### DETAILED DESCRIPTION

Various embodiments according to the invention will be described hereinafter with reference to the accompanying drawings. In general, according to one embodiment of the invention, a printed circuit board, includes: a product portion having a given outer shape; and a cutout portion disposed in the given outer shape of the product portion, for being removed away in a later production step; herein the cutout portion comprises a test coupon including two signal terminals and two parallel wiring patterns meanderingly extended respectively from the two signal terminals.

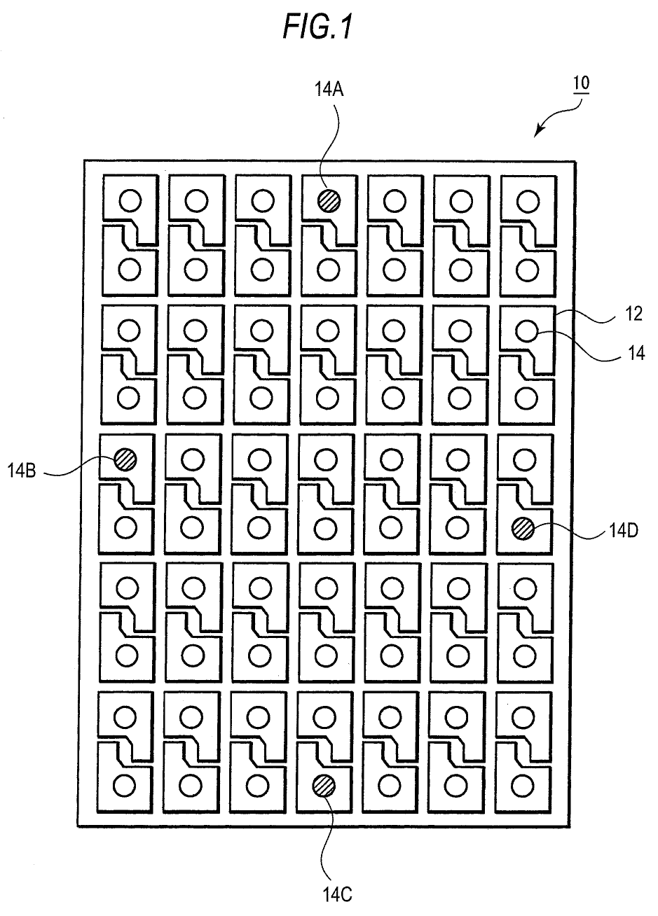

According to an embodiment, FIG. 1 shows a printed circuit board 10.

The printed circuit board 10 is an intermediate product which is produced in an intermediate step of a process of producing a printed circuit board 12 that is to be placed in an electronic apparatus. Namely, many product portions 12 are arranged in a lattice-like pattern in the single printed circuit board 10, and, in a subsequent production step, the printed circuit board 10 is cut into individual product portions (individual printed circuit boards) 12. In the embodiment, each of the individual printed circuit boards 12 is to be placed in a hard disk drive to control the operation of the hard disk drive.

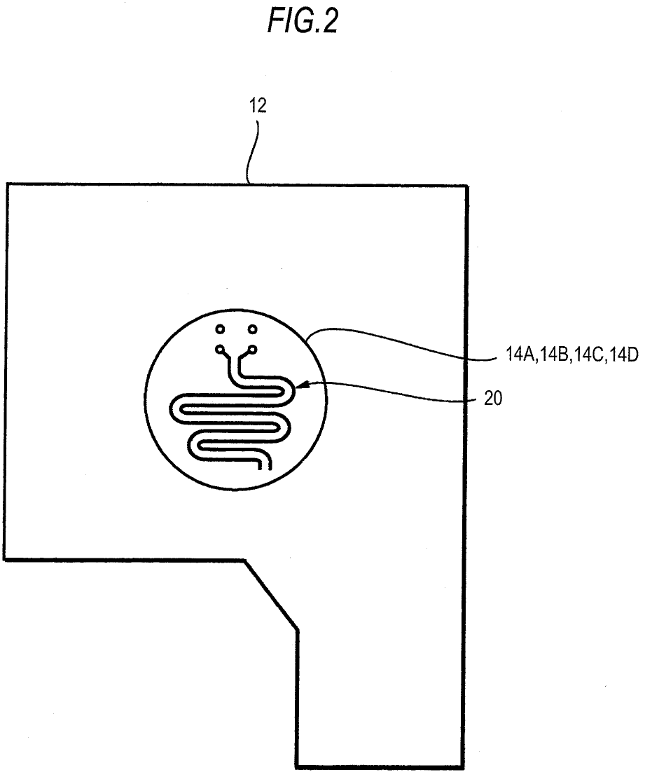

FIG. 2 enlargedly shows the individual printed circuit board 12 which is cut out from the printed circuit board 10 of FIG. 1.

In order to miniaturize a hard disk drive, the individual printed circuit board 12 has a shape (outer shape) which is similar to the outer shape of the hard disk drive, and is placed in the hard disk drive in a state where it forms a small gap with respect to another component. A spin motor for rotatingly driving a hard disk which is a storage medium is disposed in the hard disk drive. The spin motor has a cylindrical shape, and is disposed in a substantially middle of the hard disk drive. Middle portions 14, 14A, 14B, 14C, 14D of the individual printed circuit boards 12 are cut out into a circular shape in accordance with a spin motor. According to the configuration, each printed circuit board 12 can be placed in close proximity to a spin motor while avoiding interference between the printed circuit board 12 and the spin motor, so that miniaturization and thinning of the hard disk drive are realized.

In FIG. 2, the middle portions 14A, 14B, 14C, 14D of the printed circuit boards 12 are shown in a state where the portions are not cut out. Each of the middle portions 14A, 14B, 14C, 14D is a portion in which the whole periphery is completely surrounded by the corresponding printed circuit board 12. The middle portions 14A, 14B, 14C, 14D are removed away by cutting out in a subsequent production step. In the following description, the middle portions 14A, 14B, 14C, 14D are referred to as cutout portions.

Test coupons 20 for quality control are disposed in the cutout portions 14A, 14B, 14C, 14D of the printed circuit boards 12, respectively. The test coupons 20 are used for measuring the differential impedances of wirings formed in the printed circuit boards 12. In the configuration where the test coupons 20 are formed in the cutout portions 14A, 14B, 14C, 14D of the printed circuit boards 12, the production number of the individual printed circuit boards 12 is not affected by the test coupons 20. Therefore, a larger number of individual printed circuit boards 12 can be produced from the single precut printed circuit board 10, and the production cost of the individual printed circuit boards 12 can be reduced.

The test coupons 20 are not required in all of the individual printed circuit boards 12, and may be formed only at positions which are necessary for realizing quality control in the precut printed circuit board 10. As shown in FIG. 1, for example, the test coupons 20 may be formed only in the hatched cutout portions 14A, 14B, 14C, 14D.

The areas of the cutout portions 14A, 14B, 14C, 14D of the printed circuit boards 12 are small, and hence it is difficult to form the test coupons 20 inside the cutout portions 14A, 14B, 14C, 14D. In the embodiment, the shape of each test coupon 20 is improved so as to reduce the area of the test coupon 20, so that the test coupons 20 can be formed inside the cutout portions 14A, 14B, 14C, 14D. Hereinafter, the small-area test coupons 20 in the embodiment will be described.

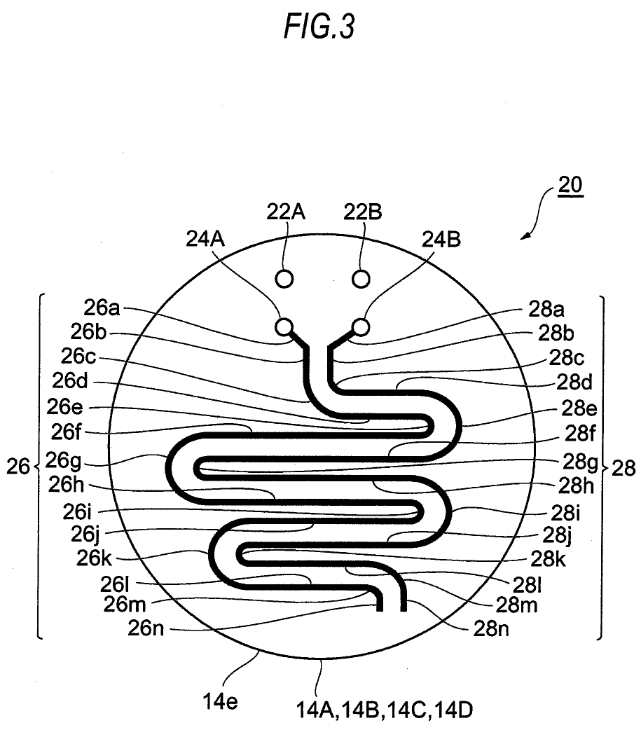

FIG. 3 enlargedly shows one of the test coupons 20 formed in the cutout portions 14A, 14B, 14C, 14D.

The test coupons 20 for quality control are formed in the cutout portions 14A, 14B, 14C, 14D. Each of the test coupons 20 has: two signal terminals 24A, 24B; two grounding terminals 22A, 22B; and two wiring patterns 26, 28 which are extended from the two signal terminals 24A, 24B, respectively. The two grounding terminals 22A, 22B are juxtaposed at positions in the vicinity of a peripheral edge 14e of the cutout portion 14A, 14B, 14C, or 14D. The two signal terminals 24A, 24B are juxtaposed at positions which are inside the cutout portion 14A, 14B, 14C, or 14D, and which are slightly inner than the two grounding terminals 22A, 22B.

The two wiring patterns 26, 28 are meanderingly extended from the two signal terminals 24A, 24B in a parallel state, respectively. Specifically, the one wiring pattern 26 is extended from the one signal terminal 24A while meandering inside the cutout portion 14A, 14B, 14C, or 14D, and the other wiring pattern 28 is extended from the other signal terminal 24B in a state where the wiring pattern is parallel to the one wiring pattern, while meandering inside the cutout portion 14A, 14B, 14C.

The shapes of the wiring patterns 26, 28 of the test coupon 20 will be described in more detail. In a portion (basal-end approaching portion) 26a, 28a where the two wiring patterns 26, 28 begin to be extended from the two signal terminals 24A, 24B, the patterns are obliquely extended so as to approach each other until the gap therebetween equals to a predetermined distance. In the subsequent portion (basal-end linearly extended portion) 26b, 28b, the two wiring patterns 26b, 28b are linearly extended toward the center of the cutout portion 14A, 14B, 14C, or 14D in a state where the patterns maintain the constant distance therebetween. In the subsequent portion (basal-end curvedly extended portion) 26c, 28c, the two wiring patterns 26c, 28c are smoothly curved so as to change the extension directions of the two wiring patterns 26, 28 by 90 degrees, in a state where the patterns maintain the constant distance therebetween.

In the subsequent portion (first linearly extended portion) 26d, 28d, the two wiring patterns 26d, 28d are linearly extended from the vicinity of the center of the cutout portion 14A, 14B, 14C, or 14D toward the right peripheral edge, in a state where the patterns maintain the constant distance therebetween. In the subsequent portion (first curvedly extended portion) 26e, 28e, the two wiring patterns 26e, 28e are smoothly curved so as to change the extension directions of the two wiring patterns 26, 28 by 180 degrees, in a state where the patterns maintain the constant distance therebetween.

In the subsequent portion (second linearly extended portion) 26f, 28f, the two wiring patterns 26f, 28f are linearly extended from the right peripheral edge side toward the left peripheral edge, in a state where the patterns maintain the constant distance therebetween. In the subsequent portion (second curvedly extended portion) 26g, 28g, the two wiring patterns 26g, 28g are smoothly curved so as to change the extension directions of the two wiring patterns 26, 28 by 180 degrees, in a state where the patterns maintain the constant distance therebetween.

In the subsequent portion (third linearly extended portion) 26h, 28h, the two wiring patterns 26h, 28h are linearly extended from the left peripheral edge side toward the right peripheral edge, in a state where the patterns maintain the constant distance therebetween. In the subsequent portion (third curvedly extended portion) 26i, 28i, the two wiring patterns 26i, 28i are smoothly curved so as to change the extension directions of the two wiring patterns 26, 28 by 180 degrees, in a state where the patterns maintain the constant distance therebetween.

In the subsequent portion (fourth linearly extended portion) 26j, 28j, the two wiring patterns 26j, 28j are linearly extended from the right peripheral edge side toward the left peripheral edge, in a state where the patterns maintain the constant distance therebetween. In the subsequent portion (fourth curvedly extended portion) 26k, 28k, the two wiring patterns 26k, 28k are smoothly curved so as to change the extension directions of the two wiring patterns 26, 28 by 180 degrees, in a state where the patterns maintain the constant distance therebetween.

In the subsequent portion (fifth linearly extended portion) 26l, 28l, the two wiring patterns 26l, 28l are linearly extended from the left peripheral edge side toward the right peripheral edge, in a state where the patterns maintain the constant distance therebetween. In the subsequent portions (terminal-end curvedly extended portions) 26m, 28m, the two wiring patterns 26m, 28m are smoothly curved so as to change the extension directions of the two wiring patterns 26, 28 by 90 degrees, in a state where the patterns maintain the constant distance therebetween. In the subsequent portion (terminal-end linearly extended portion) 26n, 28n, the two wiring patterns 26n, 28n are linearly extended toward the lower peripheral edge of the cutout portion 14A, 14B, 14C, or 14D, in a state where the patterns maintain the constant distance therebetween.

The first linearly extended portion 26d, 28d, the second linearly extended portion 26f, 28f, the third linearly extended portion 26h, 28h, the fourth linearly extended portion 26j, 28j, and the fifth linearly extended portion 26l, 28l are extended in a state where they are parallel to one another. In this way, the two wiring patterns 26, 28 have a shape in which they are meanderingly extended, and hence the long wiring patterns 26, 28 can be adequately placed in the cutout portion 14A, 14B, 14C, or 14D which has a small area.

In order to stably measure the differential impedance in high-speed signal transmission, the wiring patterns 26, 28 of each of the test coupons 20 satisfy the following conditions:

First condition: the two wiring patterns 26, 28 have the same length; and

Second condition: the curved portions of the two wiring patterns 26, 28 have a semicircular shape.

The first condition is satisfied by the provision of the even number of curvedly extended portions. In the first curvedly extended portion 26e, 28e, namely, the one wiring pattern 26 is shorter than the other wiring pattern 28, but, in the second curvedly extended portion 26g, 28g, the one wiring pattern 26 is longer than the other wiring pattern 28, with the result that the lengths of the two wiring patterns 26, 28 are equal to each other. Similarly, in the third curvedly extended portion 26i, 28i, the one wiring pattern 26 is shorter than the other wiring pattern 28, but, in the fourth curvedly extended portion 26k, 28k, the one wiring pattern 26 is longer than the other wiring pattern 28, with the result that the lengths of the two wiring patterns 26, 28 are equal to each other.

In the basal-end curvedly extended portion 26c, 28c, the one wiring pattern 26 is longer than the other wiring pattern 28, but, in the terminal-end curvedly extended portion 26m, 28m, the one wiring pattern 26 is shorter than the other wiring pattern 28, with the result that the lengths of the two wiring patterns 26, 28 are equal to each other. Also in the basal-end curvedly extended portion 26c, 28c and the terminal-end curvedly extended portion 26m, 28m, the two wiring patterns 26, 28 are equal in length to each other.

The second condition is satisfied by the semicircular shapes of the first curvedly extended portion 26e, 28e to the fourth curvedly extended portion 26k, 28k. Namely, the curved shapes of the first curvedly extended portion 26e, 28e, the second curvedly extended portion 26g, 28g, the third curvedly extended portion 26i, 28i, and the fourth curvedly extended portion 26k, 28k are semicircular shapes which are geometrically accurate, and the radii of which are equal to one another.

In each of the test coupons 20 in the embodiment, the two signal terminals 24A, 24B are placed in the vicinity of the peripheral edge 14e, and the two parallel wiring patterns 26, 28 are meanderingly extended from the two signal terminals 24A, 24B. Therefore, the test coupons 20 having the wiring patterns 26, 28 of the predetermined length can be formed in the cutout portions 14A, 14B, 14C, 14D of the small-area printed circuit board 10. Therefore, a larger number of individual printed circuit boards 12 can be produced from the single precut printed circuit board 10, and the production cost of the printed circuit boards 12 can be reduced.

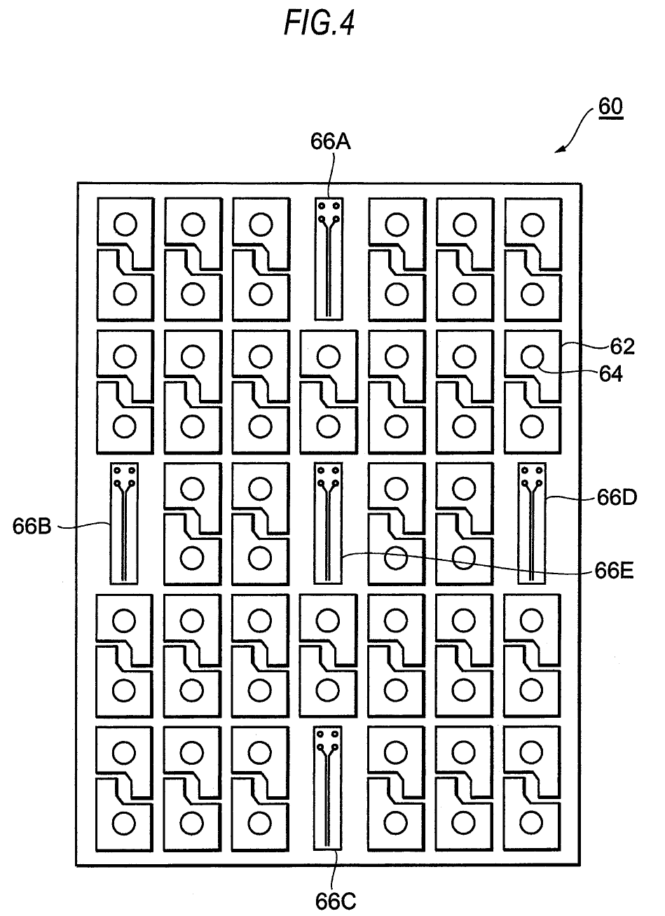

For reference, the test coupons 20 in the embodiment will be described as compared with test coupons 66A, 66B, 66C, 66D, 66E shown in FIG. 4. In the test coupons 66A, 66B, 66C, 66D, 66E shown in FIG. 4, wiring patterns are linear, and hence require a large area. In FIG. 4, therefore, the test coupons 66A, 66B, 66C, 66D, 66E are formed in portions where, in FIG. 1, the individual printed circuit boards 12 are formed. In FIG. 4, consequently, the number of individual printed circuit boards 62 which can be cut out from a single printed circuit board 60 is reduced by the formation the test coupons 66A, 66B, 66C, 66D, 66E in place of individual printed circuit boards 62. In the embodiment, by contrast, the test coupons 20 are formed in the cutout portions 14A, 14B, 14C, 14D of the printed circuit board 10, and therefore the number of the individual printed circuit boards 12 which can be cut out from the single printed circuit board 10 is increased.

In the case where the shapes of the test coupons 20 are determined as in the embodiment, the manufacturer of a hard disk drive can issue an order to the manufacturer of the printed circuit boards 12 while supplying data of the individual printed circuit boards 12 and those of the test coupons 20 to the manufacturer of the printed circuit boards. The manufacturer of the printed circuit boards 12 can place the individual printed circuit boards 12 in a lattice-like pattern in the precut printed circuit board 10, determine the positions of the test coupons 20 which are preferred for managing the quality of the printed circuit boards 12, and place the test coupons 20 in the determined cutout portions 14A, 14B, 14C, 14D of the determined printed circuit boards 12. The manufacturer of the printed circuit boards 12 may determine the positions of the test coupons 20 in accordance with a known method such as the five-point method or the nine-point method.

Control numbers are allocated to the cutout portions 14A, 14B, 14C, 14D in which the test coupon 20 is formed. This enables the positions where the test coupon 20 is formed, to be managed even after the cutout portions 14A, 14B, 14C, 14D are cut out from the printed circuit board 10.

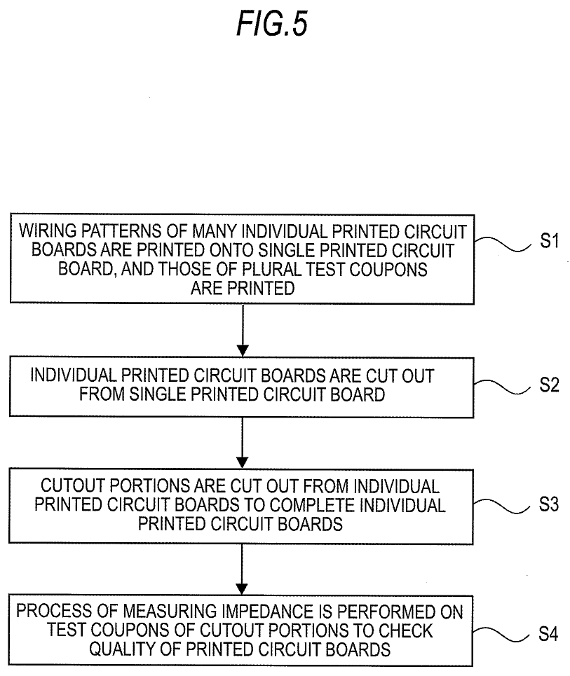

Next, a method of producing the above-described printed circuit boards 12 will be described. FIG. 5 is a flowchart showing production steps of the printed circuit boards 12.

In a first step (S1), wiring patterns of many individual printed circuit boards 12 are printed onto the single printed circuit board 10, and those of plural test coupons 20 are printed. As described above, the wiring patterns of the test coupons 20 have a shape in which two parallel wiring patterns are meanderingly extended.

In a second step (S2), individual printed circuit boards 12 are cut out from the single printed circuit board 10, so that many individual printed circuit boards 12 are obtained.

In a third step (S3), the cutout portions 14 are cut out from the individual printed circuit boards 12 to complete the individual printed circuit boards 12. The cutout portions 14A, 14B, 14C, 14D remain uncut in order to measure the difference impedance.

In a fourth step (S4), a process of measuring the difference impedance is performed on the test coupons 20 of the cutout portions 14A, 14B, 14C, 14D to check the quality of the printed circuit boards 12. In the measurement of the difference impedance, a measuring apparatus is connected to the signal terminals 24A, 24B of each of the test coupons 20, and an impedance measuring signal is sent from the measuring apparatus to the two wiring patterns 26, 28. The results of the measurements of the impedances of the test coupons 20 are statistically processed, and it is determined whether the individual printed circuit boards 12 satisfy quality standards or not.

In the above-described embodiment, the test coupons 20 are formed in the cutout portions 14A, 14B, 14C, 14D of the printed circuit boards 12 for a hard disk drive. However, the invention is not restricted to this. In another embodiment, in the case where there are small-area cutout portions in printed circuit boards for another purpose, test coupons may be formed in the cutout portions.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board, comprising:
a product portion having an outer shape; and
a cutout portion disposed in the outer shape of the product portion, configured to be removed away in a later production step;
wherein the cutout portion comprises a test coupon comprising two signal terminals and two parallel wiring patterns extended respectively from the two signal terminals.

2. The printed circuit board of claim 1,
wherein one of the two parallel wiring patterns comprises:
a plurality of linearly extended portions in which the one of the two parallel wiring patterns are linearly extended; and
a plurality of curvedly extended portions configured to connect adjacent two of the linearly extended portions.

3. The printed circuit board of claim 2,
wherein the plurality of curvedly extended portions comprises an even number of sets of the curvedly extended portions.

4. The printed circuit board of claim 3,
wherein one of the plurality of curvedly extended portions is in a semicircular shape.

5. The printed circuit board of claim 4,
wherein the test coupon further comprises:
a basal-end linearly extended portion disposed on a basal-end side of the test coupon and linearly extended from at least one of the two signal terminals;
a terminal-end linearly extended portion on a terminal-end side of the test coupon;
a basal-end curvedly extended portion configured to connect the basal-end linearly extended portion with a first one of the linearly extended portions; and
a terminal-end curvedly extended portion curvedly extended to connect a second one of the linearly extended portions with the terminal-end linearly extended portion.

6. The printed circuit board of claim 5,
wherein the test coupon comprises two grounding terminals.

7. The printed circuit board of claim 6,
wherein the test coupon comprises a test coupon for measuring impedance.

8. The printed circuit board of claim 7,
wherein the product portion printed circuit board is placed in a hard disk drive; and
the cutout portion is used for avoiding interference between a motor of the hard disk drive and the printed circuit board.

9. A method of producing a printed circuit board, comprising:
forming a print circuit board comprising a product portion and a cutout portion, the product portion comprising a wiring pattern and formed in an outer shape in a printed circuit board, the cutout portion comprising a test coupon having two parallel wiring patterns extending; and
cutting away the cutout portion from the printed circuit board to obtain the product portion.

10. The method of claim 9, further comprising:
performing a quality inspection on the printed circuit board by using the test coupon.
